(19) United States
(12) Patent Application Publication
(10) Pub. No.: US 2026/0282750 A1
(43) Pub. Date: Sep. 17, 2026

(54) PIEZOELECTRIC LAMINATE, PIEZOELECTRIC ELEMENT, AND METHOD FOR MANUFACTURING PIEZOELECTRIC LAMINATE

(71) Applicant: AGC Inc., Tokyo (JP)

(72) Inventors: Yuki AOSHIMA, Tokyo (JP); Kenichi UMEDA, Tokyo (JP)

(73) Assignee: AGC Inc., Tokyo (JP)

(21) Appl. No.: 19/664,811

(22) Filed: Apr. 30, 2026

Related U.S. Application Data
(63) Continuation of application No. PCT/JP2024/038305, filed on Oct. 28, 2024.

(30) Foreign Application Priority Data
Nov. 1, 2023 (JP) 2023-187762

(51) Int. Cl. H10N 30/00; H10N 30/067; H10N 30/076; H10N 30/853

(52) U.S. Cl. CPC H10N 30/706; H10N 30/067; H10N 30/076; H10N 30/853

(57) ABSTRACT

A piezoelectric laminate, including: a substrate; and a laminated film provided on at least one surface of the substrate, in which the laminated film includes, in order from a substrate side, an electrode layer, a base layer, and a piezoelectric thin film, the base layer and the piezoelectric thin film are in contact with each other, the base layer contains a nitrogen compound containing at least one element selected from the group consisting of Group III to VI elements, and the piezoelectric thin film has an absolute value |e₃₁^{f}| of a piezoelectric constant of 0.5 C/m² or more.

### CROSS-REFERENCE TO RELATED APPLICATIONS

This is a continuation of International Application No. PCT/JP2024/038305 filed on Oct. 28, 2024, and claims priority from Japanese Patent Application No. 2023-187762 filed on Nov. 1, 2023, the entire content of which is incorporated herein by reference.

### TECHNICAL FIELD

The present invention relates to a piezoelectric laminate, a piezoelectric element, and a method for manufacturing the piezoelectric laminate.

### BACKGROUND ART

In recent years, micro-electro-mechanical systems (MEMS) have attracted attention. The MEMS are devices in which mechanical element components, electronic circuits, and the like are integrated on a single substrate by a micromachining technique. In MEMS having functions of a sensor, a filter, a harvester, an actuator, or the like, a piezoelectric laminate or a piezoelectric element having the piezoelectric laminate is used.

The piezoelectric laminate is formed by providing a thin film (hereinafter, also abbreviated as piezoelectric thin film) made of a substance having orientation (for example, aluminum nitride) on a substrate such as silicon (Si), sapphire, or glass. The piezoelectric thin film has piezoelectric properties and pyroelectric properties due to the orientation, and is applied as a sensor, a component of a piezoelectric thin film resonator or MEMS, or the like.

In order to enhance the piezoelectric performance of the piezoelectric thin film, it is important that the piezoelectric thin film is a highly oriented piezoelectric film and that a polarity of an outermost layer is unified, but a polarity of the piezoelectric thin film is affected by a base (for example, substrate or electrode layer) or a film formation condition (Non-Patent Literatures 1 to 3).

Regarding a control of the polarity of the piezoelectric thin film, Patent Literature 1 discloses that the piezoelectric properties can be maintained at good level as long as a piezoelectric thin film is formed such that a dipole orientation degree is 75% or more. The dipole orientation degree is a proportion of crystal columns forming electric dipoles in the piezoelectric thin film whose polarity at a surface of the thin film is positive or negative and is oriented in the same direction. Patent Literature 1 discloses that, after a base layer having a function of adjusting a dipole orientation of a crystal of a piezoelectric layer is provided on a substrate, when a piezoelectric thin film layer is formed, a substrate temperature, a substrate-target distance, and a gas pressure are set to optimum values, thereby increasing a dipole orientation degree of the piezoelectric thin film layer.

Patent Literature 2 discloses that, in order to obtain effective piezoelectric characteristics in a compound having a wurtzite structure, it is necessary to unify not only crystalline orientation but also a direction of spontaneous polarization of each crystal grain in a constant direction. Patent Literature 2 discloses that, in the case of the compound having a wurtzite structure, a control of the polarization direction must be performed simultaneously with preparation thereof, and film formation conditions must be optimized.

Patent Literature 3 discloses a piezoelectric thin film resonator including a substrate, a pair of electrodes disposed along the substrate, and a piezoelectric thin film sandwiched between the pair of electrodes, in which one of the electrodes includes a first conductive layer and a polarity control layer disposed between the first conductive layer and the piezoelectric thin film and made of a metal having a standard single-electrode potential lower than that of the first conductive layer, in which the polarity control layer includes an oxide film on a piezoelectric thin film side. Patent Literature 3 discloses that a direction of the polarity of the piezoelectric thin film can be unified by the polarity control layer to improve the piezoelectric properties, and that the piezoelectric thin film is preferably an AlN film.

### CITATION LIST

### Patent Literature

Patent Literature 1: JP2004-184274A
Patent Literature 2: JP2004-346335A
Patent Literature 3: JP2006-174148A

### Non-Patent Literature

Non Patent Literature 1: Journal of Applied Physics, 2013, 113 (8)
Non Patent Literature 2: Applied Physics Letters, 2008, 93, 021903
Non Patent Literature 3: Applied Physics Letters, 2007, 90 (15), 151910

### SUMMARY OF INVENTION

### Technical Problem

As described above, Patent Literatures 1 and 2 disclose that it is necessary to optimize the film formation conditions of the piezoelectric thin film to control the polarity of the piezoelectric thin film. However, it is considered that optimum values of formation conditions of the piezoelectric thin film are different depending on a device to be used, and it is expected that the piezoelectric performance is not stable due to the device or deviation of conditions at the time of continuous film formation.

Further, as disclosed in Patent Literature 3, when an oxide film is disposed as the polarity control layer on an AlN film side serving as a piezoelectric thin film, there is a concern that AlN, which is a nitride, comes into contact with an oxide, so that a polarity of AlN is changed and the piezoelectric performance is reduced.

The present invention has been made in view of the above problems, and an object of the present invention is to provide a piezoelectric laminate including a piezoelectric thin film having improved piezoelectric performance, a piezoelectric element, and a method for manufacturing the piezoelectric laminate.

### Solution to Problem

The present inventors have found that the above problems can be solved by providing a base layer containing a nitrogen compound containing at least one element selected from the group consisting of Group III to VI elements between a piezoelectric thin film and a substrate, and have completed the present invention.

That is, one embodiment of the present invention relates to the following.

1. A piezoelectric laminate, including:
a substrate; and
a laminated film provided on at least one surface of the substrate, in which
the laminated film includes, in order from a substrate side, an electrode layer, a base layer, and a piezoelectric thin film,
the base layer and the piezoelectric thin film are in contact with each other,
the base layer contains a nitrogen compound containing at least one element selected from the group consisting of Group III to VI elements, and
the piezoelectric thin film has an absolute value |e₃₁^{f}| of a piezoelectric constant of 0.5 C/m² or more.

2. A piezoelectric laminate, including:
a substrate; and
a laminated film provided on at least one surface of the substrate, in which
the laminated film includes, in order from a substrate side, an electrode layer, a base layer, and a piezoelectric thin film,
the base layer and the piezoelectric thin film are in contact with each other, and
the base layer contains a nitrogen compound, the nitrogen compound containing at least one element selected from the group consisting of Group III to VI elements and excluding zirconium nitride.

3. The piezoelectric laminate according to 1 or 2, in which
the piezoelectric thin film contains aluminum nitride, and
the aluminum nitride has a hexagonal wurtzite structure oriented in a c-axis direction.

4. The piezoelectric laminate according to 1 or 2, in which
the base layer has a sodium chloride structure, a fluorite structure, or a perovskite structure.

5. The piezoelectric laminate according to 1 or 2, in which
the base layer has a (111) plane preferential orientation structure that is preferentially oriented in a (111) plane direction.

6. The piezoelectric laminate according to 1 or 2, in which
the base layer is a nitrogen compound containing at least one element selected from the group consisting of Zr, Hf, Y, W, and Nb.

7. The piezoelectric laminate according to 1 or 2, in which
the base layer has a thickness of 0.2 nm or more and 100 nm or less.

8. The piezoelectric laminate according to 7, in which
the base layer has the thickness of 5 nm or more and 70 nm or less.

9. The piezoelectric laminate according to 1 or 2, in which
the piezoelectric thin film has a thickness of 100 nm or more and 10 μm or less.

10. A piezoelectric element including the piezoelectric laminate according to 1 or 2.

11. A method for manufacturing a piezoelectric laminate including a substrate and a laminated film provided on at least one surface of the substrate, the method including:
preparing the substrate; and
forming an electrode layer, a base layer, and a piezoelectric thin film on at least one surface of the substrate in this order, in which
the base layer contains a nitrogen compound containing at least one element selected from the group consisting of Group III to VI elements,
the piezoelectric thin film is formed so as to be in contact with the base layer, and
the piezoelectric thin film has an absolute value |e₃₁^{f}) of a piezoelectric constant of 0.5 C/m² or more.

12. A method for manufacturing a piezoelectric laminate including a substrate and a laminated film provided on at least one surface of the substrate, the method including:
preparing the substrate; and
forming an electrode layer, a base layer, and a piezoelectric thin film on at least one surface of the substrate in this order, in which
the base layer contains a nitrogen compound, the nitrogen compound containing at least one element selected from the group consisting of Group III to VI elements and excluding zirconium nitride, and
the piezoelectric thin film is formed so as to be in contact with the base layer.

13. The method for manufacturing a piezoelectric laminate according to 11 or 12, in which
the forming is performed by a sputtering method.

### Advantageous Effects of Invention

According to the piezoelectric laminate of the present invention, the piezoelectric performance can be improved by providing the base layer containing the nitrogen compound containing at least one element selected from the group consisting of Group III to VI elements between the piezoelectric thin film and the substrate.

### BRIEF DESCRIPTION OF DRAWINGS

FIG. 1 is a schematic cross-sectional view of a piezoelectric laminate according to one embodiment of the present invention.

FIG. 2 is a schematic cross-sectional view of a piezoelectric laminate according to one embodiment of the present invention.

### DESCRIPTION OF EMBODIMENTS

Hereinafter, a content of the present invention will be described with reference to the embodiments. However, the present invention includes many different aspects, and should not be construed as being limited to the content of the embodiment exemplified below.

A first embodiment of the present invention is a piezoelectric laminate, including: a substrate; and a laminated film provided on at least one surface of the substrate, in which the laminated film includes, in order from a substrate side, an electrode layer, a base layer, and a piezoelectric thin film, the base layer and the piezoelectric thin film are in contact with each other, the base layer contains a nitrogen compound containing at least one element selected from the group consisting of Group III to VI elements, and the piezoelectric thin film has an absolute value |e₃₁^{f}| of a piezoelectric constant of 0.5 C/m² or more.

A second embodiment of the present invention is a piezoelectric laminate, including: a substrate; and a laminated film provided on at least one surface of the substrate, in which the laminated film includes, in order from a substrate side, an electrode layer, a base layer, and a piezoelectric thin film, the base layer and the piezoelectric thin film are in contact with each other, and the base layer contains a nitrogen compound, the nitrogen compound containing at least one element selected from the group consisting of Group III to VI elements and excluding zirconium nitride.

A third embodiment of the present invention is a method for manufacturing a piezoelectric laminate including a substrate and a laminated film provided on at least one surface of the substrate, the method including: preparing the substrate; and forming an electrode layer, a base layer, and a piezoelectric thin film on at least one surface of the substrate in this order, in which the base layer contains a nitrogen compound containing at least one element selected from the group consisting of Group III to VI elements, the piezoelectric thin film is formed so as to be in contact with the base layer, and the piezoelectric thin film has an absolute value |e₃₁^{f}| of a piezoelectric constant of 0.5 C/m² or more.

A fourth embodiment of the present invention is a method for manufacturing a piezoelectric laminate including a substrate and a laminated film provided on at least one surface of the substrate, the method including: preparing the substrate; and forming an electrode layer, a base layer, and a piezoelectric thin film on at least one surface of the substrate in this order, in which the base layer contains a nitrogen compound, the nitrogen compound containing at least one element selected from the group consisting of Group III to VI elements and excluding zirconium nitride, and the piezoelectric thin film is formed so as to be in contact with the base layer.

Embodiments of the present invention (hereinafter, also abbreviated as the present embodiment) include the first to fourth embodiments.

### <Piezoelectric Laminate>

A structure and a manufacturing method of a piezoelectric laminate 100 according to the present embodiment will be described with reference to the drawings.

### [Structure of Piezoelectric Laminate]

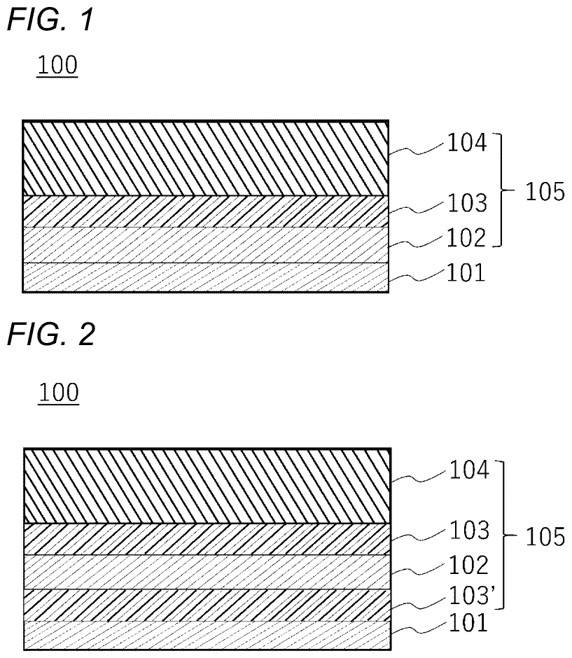

FIG. 1 is a schematic cross-sectional view illustrating the structure of the piezoelectric laminate 100 according to the present embodiment. As illustrated in FIG. 1, the piezoelectric laminate 100 includes a substrate 101 and a laminated film 105 provided on at least one surface of the substrate 101. The laminated film 105 includes, in order from a substrate side, an electrode layer 102, a base layer 103, and a piezoelectric thin film 104. Here, the base layer 103 and the piezoelectric thin film 104 are in contact with each other.

In an aspect of the present embodiment, the base layer 103 may be disposed between the substrate and the electrode layer 102. That is, as illustrated in FIG. 2, the laminated film 105 may include, in order from the substrate side, a base layer 103′, the electrode layer 102, the base layer 103, and the piezoelectric thin film 104.

### (Substrate)

A thickness, a material, and the like of the substrate 101 are not particularly limited as long as the laminated film 105 can be formed on the surface of the substrate 101, and any material known in the related art can be used. Examples of the substrate 101 include: a substrate obtained by forming silicon, diamond, or another polycrystalline film on a surface of a substrate such as silicon (Si) single crystal; a metal substrate such as stainless steel (SUS); an amorphous substrate such as glass; and a film such as polyethylene terephthalate (PET), polycarbonate (PC), a cycloolefin polymer, polyimide, or polyethylene naphthalate (PEN). The substrate 101 may have a function and a property such as conductivity allowing the substrate 101 to be used as an electrode, and the substrate 101 may be used as the electrode layer 102.

### (Electrode Layer)

The electrode layer 102 is not particularly limited, and an electrode layer commonly used for the piezoelectric laminate 100 can be used. As an electrode material constituting the electrode layer 102, for example, a film containing a metal material such as aluminum (Al), a transition metal such as molybdenum (Mo), titanium (Ti), chromium (Cr), tantalum (Ta), iridium (Ir), or nickel (Ni), a noble metal such as ruthenium (Ru), palladium (Pd), platinum (Pt), gold (Au), silver (Ag), or copper (Cu), a conductive metal oxide such as ruthenium oxide (RuO₂), or a conductive metal nitride such as chromium nitride (CrN) is used. In addition, the above materials may be combined to form the electrode layer 102.

A thickness of the electrode layer 102 is not particularly limited, and is preferably 5 nm or more from the viewpoint of forming a continuous film, for example. In addition, from the viewpoint of preventing the continuous film from being lost due to generation of cracks or the like, the above thickness is preferably 1,000 nm or less.

An arithmetic average roughness (Ra) of the electrode layer 102 is not particularly limited, and is preferably 0.1 nm or more, for example, from the viewpoint of obtaining good electrical conductivity due to the presence of crystal grains. In addition, from the viewpoint of preventing a reduction in electrical conductivity due to grain boundary scattering, the arithmetic average roughness (Ra) is preferably 10 nm or less.

A specific electrical resistance of the electrode layer 102 is preferably 10 Ω·cm or less, more preferably 1 Ω·cm or less, further preferably 1×10⁻¹ Ω·cm or less, and particularly preferably 1×10⁻² Ω·cm or less, from the viewpoint of ensuring good conductivity. The specific electrical resistance of the electrode layer 102 can be measured by using a Hall effect measuring device for the substrate on which the electrode layer 102 is formed.

### (Base Layer)

The base layer 103 is a layer formed directly or via another layer on the electrode layer 102, and improves crystalline orientation of the piezoelectric thin film 104 provided on the base layer 103. The base layer 103 is in direct contact with the piezoelectric thin film 104.

A base (for example, substrate 101 or electrode layer 102) of the piezoelectric thin film 104 and film formation conditions of the piezoelectric thin film 104 may affect the polarity and change the piezoelectric performance. The base is affected by surface contamination due to a native oxide film or carbon-based contaminants even after a cleaning process or the like, so that polarities of substances constituting the piezoelectric thin film 104 are likely to be non-uniform. In contrast, the present inventors have found that the polarity of the piezoelectric thin film 104 can be controlled and a polarity of an outermost layer can be unified by providing the base layer 103 containing a nitrogen compound containing at least one element selected from the group consisting of Group III to VI elements on the electrode layer 102.

In this manner, by controlling the polarity of the piezoelectric thin film 104 and unifying the polarity of the outermost layer, the piezoelectric performance can be effectively improved. In particular, when the base layer 103 is formed under an atmosphere of 100% of nitrogen, it is easy to obtain a crystal structure in which nitrogen is incorporated in an amount excessively larger than a stoichiometric ratio, and such an effect can be further promoted.

In the first embodiment, the base layer 103 contains the nitrogen compound containing at least one element selected from the group consisting of Group III to VI elements.

In the second embodiment, the base layer 103 contains the nitrogen compound, the nitrogen compound containing at least one element selected from the group consisting of Group III to VI elements and excluding zirconium nitride.

In the present embodiment, in a case where the nitrogen compound constituting the base layer 103 is represented by a chemical formula QN_{X} and x in the chemical formula represents a nitriding degree, the nitriding degree x is more than 0, preferably more than 1, and more preferably more than 1.1. In addition, the nitriding degree x is preferably less than 2, and more preferably less than 1.65.

The nitriding degree x can be identified by a Rutherford backscattering spectrometry (RBS) method. Further, in a case where there are a plurality of samples, the nitriding degree x for two or more samples may be measured by the above RBS method and ellipsometry, respectively, and a correlation coefficient thereof is derived, and thereafter, the nitriding degree x by the RBS method for other samples may be calculated based on a measurement result by ellipsometry.

In the present embodiment, the nitrogen compound contained in the base layer 103 is a nitride, but the nitrogen compound does not necessarily need to have a stoichiometric ratio, and may be in an overnitrided (metastable) state. In the present embodiment, it is preferable that the nitrogen compound constituting the base layer 103 is cubic and has a (111) plane main orientation, and is capable of taking the overnitrided state (metastable state). By using such a nitrogen compound, the piezoelectric thin film 104 is complemented with nitrogen, and the polarities of the substances constituting the piezoelectric thin film 104 can be easily unified.

In the first embodiment, examples of the Group III to VI elements contained in the nitrogen compound constituting the base layer 103 include scandium (Sc), yttrium (Y), titanium (Ti), zirconium (Zr), hafnium (Hf), rutherfordium (Rf), vanadium (V), niobium (Nb), tantalum (Ta), dubnium (Db), chromium (Cr), molybdenum (Mo), tungsten (W), and seaborgium (Sg). Among nitrogen compounds containing these, from the viewpoint of being cubic and having a (111) plane main orientation, and being capable of taking the overnitrided state (metastable state), nitrogen compounds of Zr, Hf, Y, W, and Nb are preferable. In the first embodiment, the nitrogen compound constituting the base layer 103 is preferably ZrN, Zr₃N₄, HIN, YN, Y₅N₁₄, WN, W₇N₁₂, NbN, and Nb₂N₃. These nitrogen compounds may be used alone or in combination of two or more thereof.

In the second embodiment, examples of the Group III to VI elements contained in the nitrogen compound constituting the base layer 103 include scandium (Sc), yttrium (Y), titanium (Ti), hafnium (Hf), rutherfordium (Rf), vanadium (V), niobium (Nb), tantalum (Ta), dubnium (Db), chromium (Cr), molybdenum (Mo), tungsten (W), and seaborgium (Sg). Among these, Hf, Y, W, and Nb are preferable from the viewpoint of being cubic and having a (111) plane main orientation, and being capable of taking the overnitrided state (metastable state). In the second embodiment, the nitrogen compound constituting the base layer 103 is preferably HfN, YN, Y₅N₁₄, WN, W₇N₁₂, NbN, and Nb₂N₃. These nitrogen compounds may be used alone or in combination of two or more thereof.

In the present embodiment, the base layer 103 preferably has a (111) plane preferential orientation structure that is preferentially oriented in a (111) plane direction, but may not necessarily be (111) plane-preferentially oriented. When the base layer 103 has the (111) plane preferential orientation structure, lattice matching with the piezoelectric thin film 104 is improved, so that the polarity of the outermost layer of the piezoelectric thin film 104 can be further unified, and the piezoelectric performance can be further improved.

In the present embodiment, it is preferable that the base layer 103 has a sodium chloride structure, a fluorite structure, or a perovskite structure. Since the base layer 103 has the above structure, the base layer 103 is easily preferentially oriented in the (111) plane direction, so that the polarity of the outermost layer of the piezoelectric thin film 104 can be further unified, and the piezoelectric performance can be further improved.

In the present embodiment, a thickness of the base layer 103 is preferably 0.2 nm or more and 120 nm or less. From the viewpoint of further enhancing the orientation of the piezoelectric thin film 104 and unifying the polarity of the outermost layer, the thickness of the base layer 103 is preferably 0.2 nm or more, more preferably 3 nm or more, and further preferably 5 nm or more. Further, from the viewpoint of improving production efficiency and reducing a cost, the thickness of the base layer 103 is preferably 120 nm or less, more preferably 100 nm or less, and further preferably 70 nm or less.

### (Piezoelectric Thin Film)

The piezoelectric thin film 104 is a layer having at least one of piezoelectric properties and pyroelectric properties, and is preferably a crystalline thin film having a hexagonal wurtzite structure oriented in a c-axis direction. In the present description, “oriented in a c-axis direction” and “c-axis oriented” mean that a peak intensity ratio of (101) plane/(002) plane in an X-ray diffraction pattern of the piezoelectric thin film measured by an out-of-plane method is less than 0.3.

The fact that piezoelectric thin film 104 has the hexagonal wurtzite structure can be confirmed by, for example, an X-ray diffraction (XRD) method, an X-ray absorption spectroscopy (XAFS, EXAFS) method, or the like. A crystalline orientation in which piezoelectric properties of the piezoelectric thin film 104 having the hexagonal wurtzite structure are exhibited is a direction of the hexagonal wurtzite structure. That is, the piezoelectric thin film 104 can achieve more excellent piezoelectric performance by a (002) plane of the hexagonal wurtzite structure being oriented (c-axis oriented).

As the piezoelectric thin film 104, for example, a thin film of aluminum nitride (AlN), ZnO, GaN, or the like is preferably used. Among these, from the viewpoint of manufacturing suitability and the viewpoint of improving the crystallinity of the base layer to be described below, it is particularly preferable that the piezoelectric thin film 104 contains AlN, and it is more preferable that the piezoelectric thin film 104 has a hexagonal wurtzite structure in which AlN is oriented in the c-axis direction.

A thickness of the piezoelectric thin film 104 is not particularly limited, and is preferably 100 nm or more, more preferably 250 nm or more, further preferably 500 nm or more, and most preferably 1,000 nm or more, from the viewpoint of ensuring better crystalline orientation and sufficiently ensuring piezoelectric characteristics. On the other hand, the thickness of the piezoelectric thin film 104 is preferably 10 μm or less, more preferably 7.5 μm or less, and further preferably 5 μm or less from the viewpoint of allowing crystal growth without generating cracks.

The piezoelectric thin film 104 preferably has high smoothness, and preferably has a small arithmetic average roughness (Ra). An arithmetic average roughness (Ra) of a surface of the piezoelectric thin film 104 is preferably 8.0 nm or less, more preferably 6.0 nm or less, further preferably 4.0 nm or less, and particularly preferably 3.5 nm or less. In addition, a lower limit of the above arithmetic average roughness (Ra) is not particularly limited, and is preferably 0.1 nm or more, further preferably 0.2 nm or more, and most preferably 0.3 nm or more, from the viewpoint of adhesion during formation of the laminated film. The arithmetic average roughness (Ra) of the surface of the piezoelectric thin film is an arithmetic average roughness of a surface on a side not in contact with the base layer 103. The arithmetic average roughness (Ra) is measured by an atomic force microscope (AFM).

In the piezoelectric thin film 104, in the X-ray diffraction pattern measured by the out-of-plane method, the peak intensity ratio of {(101) plane/(002) plane} between a (101) plane and the (002) plane is preferably 0.25 or less, more preferably 0.1 or less, further preferably 0.05 or less, and most preferably 0.01 or less, from the viewpoint of further ensuring the hexagonal wurtzite structure oriented in the c-axis direction and sufficiently ensuring the piezoelectric characteristics. A lower limit of the above peak intensity ratio is not particularly limited and may be 0.

In the first embodiment, the absolute value |e₃₁^{f}| of the piezoelectric constant of the piezoelectric thin film 104 is 0.5 C/m² or more. When the absolute value |e₃₁^{f}| of the piezoelectric constant of the piezoelectric thin film 104 is 0.5 C/m² or more, excellent piezoelectric performance is obtained. The absolute value |e₃₁^{f}| of the piezoelectric constant of the piezoelectric thin film 104 is 0.5 C/m² or more, preferably 0.8 C/m² or more, more preferably 1.1 C/m² or more, and further preferably 1.3 C/m² or more. An upper limit of the absolute value |e₃₁^{f}| of the piezoelectric constant is not particularly limited. The absolute value |e₃₁^{f}| of the piezoelectric constant can be calculated based on the following formula in accordance with IEC62047-30:2017. The piezoelectric constant e₃₁^{f} has a polarity and can take a positive or negative value, and thus is expressed in absolute value in the present description.

$${e}_{31}^{f} = {E}_{s} {t}_{s}^{2} δ / 3 {VL}^{2} ( 1 - {v}_{s} ) \qquad [ Math . 1 ]$$

e₃₁^{f}: piezoelectric constant (unit: C/m²)
Es: Young's modulus of substrate (unit: GPa)
tₛ: thickness of substrate (unit: m)
δ: end displacement (unit: m)
V: applied voltage (unit: V)
L: cantilever effective length (unit: m)
vₛ: Poisson's ratio of substrate

The piezoelectric laminate according to the present embodiment may include a layer other than the above substrate, electrode layer, base layer, and piezoelectric thin film as long as the effect of the present invention is not impaired. For example, an adhesion layer for adhering the substrate and a metal may be provided between the substrate and the electrode layer, and an adhesion layer for adhering the electrode and the base layer may be provided between the electrode layer and the base layer. In addition, at least one surface of the substrate may have a thermal oxide film. Further, an upper electrode layer or a protective layer may be provided on a surface of the piezoelectric thin film opposite a base layer and electrode layer side. Any of the above layers may be a known layer in the related art.

The piezoelectric laminate according to the present embodiment can be suitably used for a piezoelectric element. The piezoelectric element can be suitably used not only for a component utilizing a piezoelectric effect such as a gyro sensor, a shock sensor, or a microphone, but also for an element utilizing an inverse piezoelectric effect such as an actuator, an inkjet head, a speaker, a buzzer, or a resonator.

### [Method for Manufacturing Piezoelectric Laminate]

The method for manufacturing a piezoelectric laminate according to the present embodiment (hereinafter, also abbreviated as the present manufacturing method) includes: preparing a substrate; and forming an electrode layer, a base layer, and a piezoelectric thin film in this order on at least one surface of the substrate. The piezoelectric thin film preferably contains aluminum nitride, and the aluminum nitride has a hexagonal wurtzite structure oriented in the c-axis direction.

As each of the substrate, the electrode layer, and the piezoelectric thin film in the present embodiment, the substrate 101, the electrode layer 102, and the piezoelectric thin film 104 in the present embodiment described in the above [Structure of Piezoelectric Laminate] can be used, respectively.

As the base layer in the third embodiment, the base layer 103 in the first embodiment described in the above [Structure of Piezoelectric Laminate] can be used.

As the base layer in the fourth embodiment, the base layer 103 in the second embodiment described in the above [Structure of Piezoelectric Laminate] can be used.

The piezoelectric laminate obtained in the present manufacturing method is preferably the piezoelectric laminate 100 described in the above [Structure of Piezoelectric Laminate].

That is, in the piezoelectric laminate obtained by the manufacturing method of the third embodiment, the base layer and the piezoelectric thin film are in contact with each other, the base layer contains a nitrogen compound containing at least one element selected from the group consisting of Group III to VI elements, and the absolute value |e₃₁^{f}| of the piezoelectric constant of the piezoelectric thin film is 0.5 C/m² or more. The absolute value |e₃₁^{f}| of the piezoelectric constant of the piezoelectric thin film is 0.5 C/m² or more, preferably 0.8 C/m² or more, more preferably 1.1 C/m² or more, and further preferably 1.3 C/m² or more. An upper limit of the absolute value |e₃₁^{f}| of the piezoelectric constant is not particularly limited.

In addition, in the piezoelectric laminate obtained by the manufacturing method of the fourth embodiment, the base layer and the piezoelectric thin film are in contact with each other, the base layer contains a nitrogen compound, the nitrogen compound containing at least one element selected from the group consisting of Group III to VI elements and excluding zirconium nitride.

### (Preparation of Substrate)

As the substrate, for example, the above-described substrate 101 can be used, but a commercially available substrate or a prepared substrate may be used.

### (Formation of Laminated Film)

The laminated film 105 is formed on at least one surface of the substrate 101 prepared above. The laminated film 105 is formed in the order of the electrode layer 102, the base layer 103, and the piezoelectric thin film 104, and any of these can be formed by adopting, for example, a physical vapor film formation method, a chemical vapor deposition method (CVD method), or the like. Examples of the physical vapor film formation method include a physical vapor deposition method, a PVD method, and a sputtering method. Among those, the sputtering method is particularly preferable from the viewpoint of being able to control a doping amount in a wide range, and a magnetron sputtering method and a digital sputtering method are still particularly preferable.

The electrode layer 102 may be provided directly on at least one surface of the substrate 101 or may be provided thereon via an adhesion layer or the like. The electrode layer may be formed of a single layer or two or more layers.

The base layer 103 may be provided directly on the electrode layer 102 or may be provided thereon via an adhesion layer or the like. The base layer 103 contains a nitrogen compound containing at least one element selected from the group consisting of Group III to VI elements, and when the base layer 103 is formed by a sputtering method, a composition (for example, value of nitriding degree) of the nitrogen compound can be adjusted by controlling a film formation condition thereof. The film formation conditions include, for example, a temperature of the substrate 101 during film formation, a film formation pressure, a composition of an introduced gas, a target composition, and a post-heat treatment temperature.

The nitrogen compound constituting the base layer 103 may contain impurities such as carbon and oxygen inevitably introduced during film formation at a maximum of about 10 at %. In the case where the sputtering method is used, a maximum of about 10 at % of impurities contained in a target is allowed. Examples of the impurities contained in the target (for example, Zr or Hf) containing Group III to VI elements constituting the base layer 103 include Hf, Ti, Sc, V, Nb, Ta, Cr, Mo, W, O, and C.

When the base layer 103 is formed, a doping element may be contained. The doping element is preferably contained within a range allowing the piezoelectric thin film 104 to maintain the hexagonal wurtzite structure. For example, in a case where the piezoelectric thin film 104 contains AlN, by containing an element such as Sc, Y, Mg, Ca, Sr, Zr, Hf, V, or Nb as the doping element, strain is applied to AlN, and the piezoelectric performance is improved. Particularly, the Sc element is preferable for improving the piezoelectric performance, and can be doped up to about 43 at % in this case.

The nitriding degree x of the nitrogen compound containing at least one element selected from the group consisting of Group III to VI elements in the base layer 103 can be adjusted by a flow rate of a nitrogen gas during film formation. For example, in a case where the nitriding degree x is adjusted to be in a range of 0<x<2, the flow rate of the nitrogen gas is preferably 20% or more, and particularly preferably 40% or more, in terms of a ratio of {N₂/(Ar+N₂)}. Further, even in a case where the above ratio is 100%, an amount of nitrogen can be adjusted to a larger amount by increasing the film formation pressure by increasing a flow rate of nitrogen, and the nitriding degree x can be set to a value close to 2.

The film formation pressure is preferably 0.05 Pa or more, and more preferably 0.1 Pa or more, from the viewpoint of crystal density and orientation. In addition, the film formation pressure is preferably 10 Pa or less, and more preferably 1 Pa or less.

A substrate temperature during film formation of the base layer 103 is preferably room temperature to 600° C. or lower, and further preferably 250° C. or lower.

In order to fully exhibit the effect of the base layer 103, it is preferable not to break vacuum not only during formation of the base layer 103 but also throughout continuous formation of all of the electrode layer 102, the base layer 103, and the piezoelectric thin film 104. In particular, when the vacuum is broken during film formation of the base layer 103 and the piezoelectric thin film 104, oxygen may be mixed into the base layer 103 as an impurity, and properties of the base layer 103 may not be utilized. In this case, good interface properties cannot be obtained, so that it is preferable to continuously form the film under vacuum.

The piezoelectric thin film 104 is directly formed on the base layer 103. The piezoelectric thin film 104 can be formed by a known method in the related art using a known material in the related art. For example, in a case of a thin film of aluminum nitride having a hexagonal wurtzite structure oriented in the c-axis direction, film formation conditions in a case of film formation by the sputtering method can be, for example, a pressure of 0.05 Pa to 10 Pa, a nitrogen gas partial pressure ratio of 20% to 100%, and a substrate temperature of 25° C. to 200° C.

The nitrogen compound constituting the piezoelectric thin film 104 may contain impurities such as carbon and oxygen inevitably introduced during film formation at a maximum of about 10 at %. In the case where the sputtering method is used, a maximum of about 10 at % of impurities contained in a target is allowed. Examples of the impurities contained in the target (for example, Al when the material is AlN) containing the element constituting the piezoelectric thin film 104 include Hf, Ti, Sc, V, Nb, Ta, Cr, Mo, W, O, and C.

As described above, the following matters are disclosed in the present description.

1. A piezoelectric laminate, including:
a substrate; and
a laminated film provided on at least one surface of the substrate, in which
the laminated film includes, in order from a substrate side, an electrode layer, a base layer, and a piezoelectric thin film,
the base layer and the piezoelectric thin film are in contact with each other,
the base layer contains a nitrogen compound containing at least one element selected from the group consisting of Group III to VI elements, and
the piezoelectric thin film has an absolute value |e₃₁^{f}| of a piezoelectric constant of 0.5 C/m² or more.

2. A piezoelectric laminate, including:
a substrate; and
a laminated film provided on at least one surface of the substrate, in which
the laminated film includes, in order from a substrate side, an electrode layer, a base layer, and a piezoelectric thin film,
the base layer and the piezoelectric thin film are in contact with each other, and
the base layer contains a nitrogen compound, the nitrogen compound containing at least one element selected from the group consisting of Group III to VI elements and excluding zirconium nitride.

3. The piezoelectric laminate according to 1 or 2, in which
the piezoelectric thin film contains aluminum nitride, and
the aluminum nitride has a hexagonal wurtzite structure oriented in a c-axis direction.

4. The piezoelectric laminate according to 1 or 2, in which
the base layer has a sodium chloride structure, a fluorite structure, or a perovskite structure.

5. The piezoelectric laminate according to any one of 1 to 4, in which
the base layer has a (111) plane preferential orientation structure that is preferentially oriented in a (111) plane direction.

6. The piezoelectric laminate according to any one of 1 to 5, in which
the base layer is a nitrogen compound containing at least one element selected from the group consisting of Zr, Hf, Y, W, and Nb.

7. The piezoelectric laminate according to any one of 1 to 6, in which
the base layer has a thickness of 0.2 nm or more and 100 nm or less.

8. The piezoelectric laminate according to 7, in which
the base layer has the thickness of 5 nm or more and 70 nm or less.

9. The piezoelectric laminate according to any one of 1 to 8, in which
the piezoelectric thin film has a thickness of 100 nm or more and 10 μm or less.

10. A piezoelectric element including the piezoelectric laminate according to any one of 1 to 9.

11. A method for manufacturing a piezoelectric laminate including a substrate and a laminated film provided on at least one surface of the substrate, the method including:
preparing the substrate; and
forming an electrode layer, a base layer, and a piezoelectric thin film on at least one surface of the substrate in this order, in which
the base layer contains a nitrogen compound containing at least one element selected from the group consisting of Group III to VI elements,
the piezoelectric thin film is formed so as to be in contact with the base layer, and
the piezoelectric thin film has an absolute value |e₃₁^{f}) of a piezoelectric constant of 0.5 C/m² or more.

12. A method for manufacturing a piezoelectric laminate including a substrate and a laminated film provided on at least one surface of the substrate, the method including:
preparing the substrate; and
forming an electrode layer, a base layer, and a piezoelectric thin film on at least one surface of the substrate in this order, in which
the base layer contains a nitrogen compound, the nitrogen compound containing at least one element selected from the group consisting of Group III to VI elements and excluding zirconium nitride, and
the piezoelectric thin film is formed so as to be in contact with the base layer.

13. The method for manufacturing a piezoelectric laminate according to 11 or 12, in which
the forming is performed by a sputtering method.

### EXAMPLES

Hereinafter, the present invention is specifically described with reference to Examples, but the present invention is not limited thereto.

Examples 1 to 6, 8, 9, 11, and 13 to 32 are inventive examples, and Examples 7, 10, and 12 are comparative examples.

### Example 1

A piezoelectric laminate 100 in which a base layer 103 and a piezoelectric thin film 104 were formed in this order on a substrate 101 and an electrode layer 102 was prepared by the following procedures (1) to (3).

### (1) Preparation of Substrate 101 and Electrode Layer 102

A 25 mm×25 mm×0.625 mm conductive silicon substrate (abbreviated as “conductive Si” in table) was used as the substrate 101 and the electrode layer 102.

The substrate 101 in Example 1 is a conductive Si and also functions as the electrode layer 102. Accordingly, in Table 1, an item of “electrode layer” of Example 1 is indicated by oblique lines, but the piezoelectric laminate 100 of Example 1 has a configuration including the electrode layer 102.

### (2) Formation of Base Layer 103

A base layer 103 was formed on a surface of one of the substrate 101 and the electrode layer 102 by a sputtering method according to the following procedure under the following conditions.

Formation of the base layer 103 was performed under the following conditions after placing the substrate 101 and the electrode layer 102 in a vacuum chamber of a sputtering device, then evacuating the vacuum chamber, and lowering a chamber pressure to 10⁻³ Pa or less, without breaking the vacuum.
Film formation device A: vertical in-line sputtering system (manufactured by ULVAC, Inc.)
Sputtering target material: Zr metal (purity 2N2 (value including Hf), manufactured by TANAKA PRECIOUS METAL TECHNOLOGIES Co., Ltd.)
Introduced gas: 80 sccm of nitrogen gas (purity=99.9% or more)
Film formation pressure: 0.4 Pa
Thickness: 10 nm
Substrate heating temperature: room temperature

### (3) Formation of Piezoelectric Thin Film 104

Aluminum nitride (AlN) was formed as the piezoelectric thin film 104 on the base layer 103 by the following procedure.

Following the formation of the base layer 103, the chamber pressure was lowered to 10⁻³ Pa or less, and the piezoelectric thin film 104 was then formed without breaking the vacuum.

The formation of the piezoelectric thin film 104 was performed by the same device as the device for forming the base layer 103.
Sputtering target material: Al metal (purity: 3N, manufactured by Kojundo Chemical Laboratory Co., Ltd.)
Introduced gas: mixed gas of 16 sccm of nitrogen gas (purity=99.9% or more) and 24 sccm of Ar gas (purity=99.9% or more)
Film formation pressure: 0.2 Pa
Substrate heating temperature: room temperature
Thickness: 1,000 nm

### Examples 2 to 9

In Examples 2 to 9, piezoelectric laminates 100 were prepared in the same manner to perform film formation as in Example 1 except that the formation conditions of the base layer 103 and the piezoelectric thin film 104 were changed as shown in Tables 1 and 2.

### Examples 10 and 11

Piezoelectric laminates 100 were prepared in the same manner to perform film formation as in Example 1 except that the following device B was used as the film formation device in the formation of the base layer 103 and the piezoelectric thin film 104, and the formation conditions of the base layer 103 and the piezoelectric thin film 104 were changed as shown in Table 2.

Film Formation Device B: Deposition-Down Type in-Line Sputtering System

In Example 11, a sample of the piezoelectric laminate 100 was processed with a focused ion beam (FIB, Helios 1200 manufactured by FEI Company) to obtain a thin sample, and the thin sample was observed with a transmission electron microscope (TEM, NEOARM manufactured by JEOL Ltd.), and a crystal and an orientation thereof were identified from a TEM high-resolution image by fast Fourier transform analysis (FFT analysis). As a result, a ZrN film of the base layer 103 was (111) plane-oriented in a lamination direction.

### Example 12

A piezoelectric laminate 100 was prepared in the same manner to perform film formation as in Example 1 except that the following device C was used as the film formation device in the formation of the base layer 103 and the piezoelectric thin film 104, and the formation conditions of the base layer 103 and the piezoelectric thin film 104 were changed as shown in Table 2.

### Film Formation Device C: Post-Nitriding Sputtering Device

### Example 13

A piezoelectric laminate 100 was prepared in the same manner to perform film formation as in Example 12 except that the formation conditions of the base layer 103 were changed as shown in Table 2, and HfN was used as the material of the base layer 103 to form a film under the following conditions.

### Film Formation Device C: Post-Nitriding Sputtering Device

Sputtering target material: Hf metal (manufactured by Kojundo Chemical Lab. Co., Ltd.)
Introduced gas: 30 sccm of nitrogen gas (purity=99.9% or more)
Film formation pressure: 0.35 Pa
Thickness: 10 nm
Substrate heating temperature: room temperature

### Example 14

A piezoelectric laminate 100 in which an electrode layer 102, a base layer 103, and a piezoelectric thin film 104 were formed in this order on a substrate 101 was prepared by the following procedures (1) to (4).

### (1) Preparation of Substrate 101

A 25 mm×25 mm×0.625 mm silicon substrate in which 1 μm was thermally oxidized from both surfaces (abbreviated as “SiSiO” in table) was used as the substrate 101.

### (2) Formation of Electrode Layer 102

An electrode layer 102 was provided on one surface of the substrate 101 by the following procedures. As the electrode layer 102, only a single layer of Pt was formed.

The formation of the electrode layer was performed after placing the substrate in a vacuum chamber of a sputtering device, then evacuating the vacuum chamber, and lowering the chamber pressure to 10⁻³ Pa or less.
Film formation device A: vertical in-line sputtering system (manufactured by ULVAC, Inc.)
Sputtering target material: Pt metal
Introduced gas: 23 sccm of Ar gas (purity=99.9% or more)
Film formation pressure: 0.4 Pa
Thickness: 150 nm
Substrate heating temperature: room temperature

### (3) Formation of Base Layer 103

A base layer 103 was formed on a surface of the electrode layer 102 by a sputtering method according to the following procedure under the following conditions.

The formation of the base layer 103 was performed under the following conditions after placing the substrate 101 in a vacuum chamber of a sputtering device, then evacuating the vacuum chamber, and lowering the chamber pressure to 10⁻³ Pa or less, without breaking the vacuum.
Film formation device A: vertical in-line sputtering system (manufactured by ULVAC, Inc.)
Sputtering target material: Zr metal (purity 2N2 (value including Hf), manufactured by TANAKA PRECIOUS METAL TECHNOLOGIES Co., Ltd.)
Introduced gas: 80 sccm of nitrogen gas (purity=99.9% or more)
Film formation pressure: 0.4 Pa
Thickness: 5 nm
Substrate heating temperature: room temperature

### (4) Formation of Piezoelectric Thin Film 104

Aluminum nitride (AlN) was formed as the piezoelectric thin film 104 on the base layer 103 by the following procedure.

Following the formation of the base layer 103, the chamber pressure was lowered to 10⁻³ Pa or less, and the piezoelectric thin film 104 was then formed without breaking the vacuum.

The formation of the piezoelectric thin film 104 was performed by the same device as the device for forming the base layer 103.
Sputtering target material: Al metal (purity: 3N, manufactured by Kojundo Chemical Laboratory Co., Ltd.)
Introduced gas: mixed gas of 20 sccm of nitrogen gas (purity=99.9% or more) and 20 sccm of Ar (purity=99.9% or more)
Film formation pressure: 0.2 Pa
Substrate heating temperature: room temperature
Thickness: 1,000 nm

### Examples 15 to 19

In Examples 15 to 19, piezoelectric laminates 100 were prepared in the same manner to perform film formation as in Example 14 except that the formation conditions of the base layer 103 and the piezoelectric thin film 104 were changed as shown in Table 3.

### Examples 20 to 24

Piezoelectric laminates 100 were prepared in the same manner to perform film formation as in Example 14 except that a 25 mm×25 mm×0.7 mm alkali-free glass (abbreviated as “alkali-free” in table) was used as the substrate 101, and the formation conditions of the base layer 103 and the piezoelectric thin film 104 were changed as shown in Table 4.

### Example 25

A piezoelectric laminate 100 in which an electrode layer 102, a base layer 103, and a piezoelectric thin film 104 were formed in this order on a substrate 101 was prepared by the following procedures (1) to (4).

### (1) Preparation of Substrate 101

A 25 mm×25 mm×0.7 mm alkali-free glass (abbreviated as “alkali-free” in table) was used as the substrate 101.

### (2) Formation of Electrode Layer 102

An electrode layer 102 was provided on one surface of the substrate 101 by the following procedures. As the electrode layer 102, only a single layer of ITO was formed.

The formation of the electrode layer was performed after placing the substrate in a vacuum chamber of a sputtering device, then evacuating the vacuum chamber, and lowering the chamber pressure to 10⁻³ Pa or less.
Film formation device A: vertical in-line sputtering system (manufactured by ULVAC, Inc.)
Sputtering target material: In₂O₃: SnO₂=90 wt %: 10 wt % (ITO, manufactured by Mitsui Kinzoku Company, Limited)
Introduced gas: 80 sccm of Ar gas (purity=99.9% or more) and 0.8 sccm of O₂ gas (purity=99.9% or more)
Film formation pressure: 0.5 Pa
Thickness: 120 nm
Substrate heating temperature: room temperature

### (3) Formation of Base Layer 103

A base layer 103 was formed on a surface of the electrode layer 102 by a sputtering method by the following procedure under the following conditions.

The formation of the base layer 103 was performed under the following conditions after placing the substrate 101 in a vacuum chamber of a sputtering device, then evacuating the vacuum chamber, and lowering the chamber pressure to 10⁻³ Pa or less, without breaking the vacuum.
Film formation device A: vertical in-line sputtering system (manufactured by ULVAC, Inc.)
Sputtering target material: Zr metal (purity 2N2 (value including Hf), manufactured by TANAKA PRECIOUS METAL TECHNOLOGIES Co., Ltd.)
Introduced gas: 80 sccm of nitrogen gas (purity=99.9% or more)
Film formation pressure: 0.4 Pa
Thickness: 10 nm
Substrate heating temperature: room temperature

### (4) Formation of Piezoelectric Thin Film 104

Aluminum nitride (AlN) was formed as the piezoelectric thin film 104 on the base layer 103 by the following procedure.

Following the formation of the base layer 103, the chamber pressure was lowered to 10⁻³ Pa or less, and the piezoelectric thin film 104 was then formed without breaking the vacuum.

The formation of the piezoelectric thin film 104 was performed by the same device as the device for forming the base layer 103.
Sputtering target material: Al metal (purity: 3N, manufactured by Kojundo Chemical Laboratory Co., Ltd.)
Introduced gas: mixed gas of 20 sccm of nitrogen gas (purity=99.9% or more) and 20 sccm of Ar gas (purity=99.9% or more)
Film formation pressure: 0.2 Pa
Substrate heating temperature: room temperature
Thickness: 1,000 nm

### Example 26

A piezoelectric laminate 100 was prepared in the same manner to perform film formation as in Example 25 except that a 25 mm×25 mm×0.7 mm quartz glass (abbreviated as “quartz” in table) was used as the substrate 101, and the formation conditions of the base layer 103 and the piezoelectric thin film 104 were changed as shown in Table 4.

### Example 28

A piezoelectric laminate 100 in which a base layer 103′, an electrode layer 102, a base layer 103, and a piezoelectric thin film 104 were formed in this order on a substrate 101 was prepared by the following procedures (1) to (5).

### (1) Preparation of Substrate 101

A 25 mm×25 mm×0.7 mm silicon substrate in which 1 μm was thermally oxidized from both surfaces (abbreviated as “SiSiO” in table) was used as the substrate 101.

### (2) Formation of Base Layer 103′

A base layer 103′ was formed on one surface of the substrate 101 by a sputtering method according to the following procedure under the following conditions.

The formation of the base layer 103′ was performed under the following conditions after placing the substrate 101 in a vacuum chamber of a sputtering device, then evacuating the vacuum chamber, and lowering the chamber pressure to 10⁻³ Pa or less, without breaking the vacuum.
Film formation device A: vertical in-line sputtering system (manufactured by ULVAC, Inc.)
Sputtering target material: Zr metal [purity: 2N2 (value including Hf), manufactured by TANAKA PRECIOUS METAL TECHNOLOGIES Co., Ltd.]
Introduced gas: 80 sccm of nitrogen gas (purity=99.9% or more)
Film formation pressure: 0.4 Pa
Thickness: 10 nm
Substrate heating temperature: room temperature

### (3) Formation of Electrode Layer 102

An electrode layer 102 was provided on one surface of the base layer 103′ by the following procedures. As the electrode layer 102, only a single layer of Ti was formed.

The formation of the electrode layer was performed after placing the substrate in a vacuum chamber of a sputtering device, then evacuating the vacuum chamber, and lowering the chamber pressure to 10⁻³ Pa or less.
Film formation device A: vertical in-line sputtering system (manufactured by ULVAC, Inc.)
Sputtering target material: Ti metal (manufactured by Kojundo Chemical Laboratory Co., Ltd.)
Introduced gas: 80 sccm of Ar gas (purity=99.9% or more)
Film formation pressure: 0.45 Pa
Thickness: 100 nm
Substrate heating temperature: room temperature

### (4) Formation of Base Layer 103

A base layer 103 was formed on the electrode layer 102 by a sputtering method under the same conditions as in the formation of the base layer 103′.

### (5) Formation of Piezoelectric Thin Film 104

Aluminum nitride (AlN) was formed as the piezoelectric thin film 104 on the base layer 103 by the following procedure.

Following the formation of the base layer 103, the chamber pressure was lowered to 10⁻³ Pa or less, and the piezoelectric thin film 104 was then formed without breaking the vacuum.

The formation of the piezoelectric thin film 104 was performed by the same device as the device for forming the base layer 103.
Sputtering target material: Al metal (3N, manufactured by Kojundo Chemical Laboratory Co., Ltd.)
Introduced gas: 40 sccm of nitrogen gas (purity=99.9% or more) Film formation pressure: 0.2 Pa
Substrate heating temperature: room temperature
Thickness: 1,000 nm

### Example 27

A piezoelectric laminate 100 was prepared in the same manner to perform film formation as in Example 28 except that a base layer 103′ was not formed.

### Example 29

A piezoelectric laminate 100 was prepared in the same manner to perform film formation as in Example 27 except that the formation conditions of the piezoelectric thin film 104 were changed as shown in Table 5.

### Example 30

A piezoelectric laminate 100 was prepared in the same manner to perform film formation as in Example 28 except that a 100 mm×100 mm×2 mm alkali-free glass (abbreviated as “alkali-free” in table) was used as the substrate 101 and a base layer 103′ was not formed.

### Example 31

A piezoelectric laminate 100 was prepared in the same manner to perform film formation as in Example 28 except that a 100 mm×100 mm×2 mm alkali-free glass was used as the substrate 101.

### Example 32

A piezoelectric laminate 100 was prepared in the same manner to perform film formation as in Example 31 except that a 100 mm×100 mm×2 mm quartz glass (abbreviated as “quartz” in table) was used as the substrate 101.

### <Evaluation>

Piezoelectric response of each of the obtained piezoelectric laminates was calculated based on the following formula in accordance with IEC62047-30:2017.

$${e}_{31}^{f} = {E}_{s} {t}_{s}^{2} δ / 3 {VL}^{2} ( 1 - {v}_{s} ) \qquad [ Math . 2 ]$$

e₃₁^{f}: piezoelectric constant (unit: C/m²)
Es: Young's modulus of substrate (unit: GPa)
tₛ: thickness of substrate (unit: m)
δ: end displacement (unit: m)
V: applied voltage (unit: V)
L: cantilever effective length (unit: m)
vₛ: Poisson's ratio of substrate

For measurement of the piezoelectric response, a function generator (WF1974 manufactured by NF Corporation) was used as an AC power supply, and a voltage obtained by a laser Doppler (LV1800 manufactured by ONO SOKKI Co., Ltd.) was converted into a displacement to obtain a voltage amplitude/2nf (frequency) using the laser Doppler and an oscilloscope (TBS1072C manufactured by Tektronix, Inc.). Results are shown in Tables 1 to 5.

TABLE 1

| Example | | 1 | 2 | 3 | 4 | 5 | 6 |
|---|---|---|---|---|---|---|---|
| Substrate | | Conductive | Conductive | Conductive | Conductive | Conductive | Conductive |
| | | Si | Si | Si | Si | Si | Si |
| Film formation device | | A | A | A | A | A | A |
| Electrode layer | Material | | | | | | |
| | Thickness (nm) | | | | | | |
| Base layer | Material | ZrN | ZrN | ZrN | ZrN | ZrN | ZrN |
| | Flow rate of nitrogen gas | 80 | 80 | 80 | 80 | 80 | 80 |
| | (sccm) | | | | | | |
| | Flow rate of Ar gas (sccm) | 0 | 0 | 0 | 0 | 0 | 0 |
| | Thickness (nm) | 10 | 10 | 5 | 10 | 20 | 50 |
| Piezoelectric thin | Film formation pressure | 0.2 | 0.2 | 0.2 | 0.2 | 0.2 | 0.2 |
| film (aluminum | (Pa) | | | | | | |
| nitride) | Power density (W/cm²) | 7.1 | 7.1 | 7.1 | 7.1 | 7.1 | 7.1 |
| | Flow rate of nitrogen gas | 16 | 40 | 20 | 20 | 20 | 20 |
| | (sccm) | | | | | | |
| | Flow rate of Ar gas (sccm) | 24 | 0 | 20 | 20 | 20 | 20 |
| | Thickness (nm) | 1,000 | 1,000 | 1,000 | 1,000 | 1,000 | 1,000 |
| Piezoelectric | C/m² | 1.5 | 1.2 | 1.1 | 1.2 | 1.1 | 1.2 |
| constant e₃₁^{f} | | | | | | | |

TABLE 2

| Example | | 7 | 8 | 9 | 10 | 11 | 12 | 13 |
|---|---|---|---|---|---|---|---|---|
| Substrate | | Conductive | Conductive | Conductive | Conductive | Conductive | Conductive | Conductive |
| | | Si | Si | Si | Si | Si | Si | Si |
| Film formation device | | A | A | A | B | B | C | C |
| Electrode | Material | | | | | | | |
| layer | Thickness (nm) | | | | | | | |
| Base layer | Material | | ZrN | ZrN | | ZrN | | HfN |
| | Flow rate of nitrogen gas | | 80 | 80 | | 200 | | 30 |
| | (sccm) | | | | | | | |
| | Flow rate of Ar gas (sccm) | | 0 | 0 | | 0 | | 0 |
| | Thickness (nm) | 0 | 10 | 10 | 0 | 10 | 0 | 10 |
| Piezoelectric | Film formation pressure | 0.2 | 0.2 | 0.2 | 0.1 | 0.1 | 0.19 | 0.19 |
| thin film | (Pa) | | | | | | | |
| (aluminum | Power density (W/cm²) | 3.57 | 3.57 | 7.1 | 3.6 | 3.6 | 10.2 | 10.2 |
| nitride) | Flow rate of nitrogen gas | 40 | 40 | 40 | 200 | 200 | 15 | 15 |
| | (sccm) | | | | | | | |
| | Flow rate of Ar gas (sccm) | 0 | 0 | 0 | 0 | 0 | 0 | 0 |
| | Thickness (nm) | 1,000 | 1,000 | 500 | 1,000 | 1,000 | 500 | 500 |
| Piezoelectric | C/m² | 0.3 | 0.5 | 1.2 | 0.3 | 0.5 | 0.3 | 0.8 |
| constant e₃₁^{f} | | | | | | | | |

TABLE 3

| Example | | 14 | 15 | 16 | 17 | 18 | 19 |
|---|---|---|---|---|---|---|---|
| Substrate | | SiSiO | SiSiO | SiSiO | SiSiO | SiSiO | SiSiO |
| Film formation device | | A | A | A | A | A | A |
| Electrode layer | Material | Pt | Pt | Pt | Pt | Pt | Pt |
| | Thickness (nm) | 150 | 150 | 150 | 150 | 150 | 150 |
| Base layer | Material | ZrN | ZrN | ZrN | ZrN | ZrN | ZrN |
| | Flow rate of nitrogen gas (sccm) | 80 | 80 | 80 | 80 | 80 | 80 |
| | Flow rate of Ar gas (sccm) | 0 | 0 | 0 | 0 | 0 | 0 |
| | Thickness (nm) | 5 | 20 | 50 | 30 | 50 | 70 |
| Piezoelectric thin | Film formation pressure (Pa) | 0.2 | 0.2 | 0.2 | 0.2 | 0.2 | 0.2 |
| film (aluminum | Power density (W/cm²) | 7.1 | 7.1 | 7.1 | 7.1 | 7.1 | 7.1 |
| nitride) | Flow rate of nitrogen gas (sccm) | 20 | 20 | 20 | 40 | 40 | 40 |
| | Flow rate of Ar gas (sccm) | 20 | 20 | 20 | 0 | 0 | 0 |
| | Thickness (nm) | 1,000 | 1,000 | 1,000 | 1,000 | 1,000 | 1,000 |
| Piezoelectric | C/m² | 1.3 | 1.7 | 1.8 | 1.6 | 1.5 | 1.3 |
| constant e₃₁^{f} | | | | | | | |

TABLE 4

| Example | | 20 | 21 | 22 | 23 | 24 | 25 | 26 |
|---|---|---|---|---|---|---|---|---|
| Substrate | | Alkali- | Alkali- | Alkali- | Alkali- | Alkali- | Alkali- | Quartz |
| | | free | free | free | free | free | free | |
| Film formation device | | A | A | A | A | A | A | A |
| Electrode layer | Material | Pt | Pt | Pt | Pt | Pt | ITO | ITO |
| | Thickness (nm) | 150 | 150 | 150 | 150 | 150 | 120 | 120 |
| Base layer | Material | ZrN | ZrN | ZrN | ZrN | ZrN | ZrN | ZrN |
| | Flow rate of nitrogen gas (sccm) | 80 | 80 | 80 | 80 | 80 | 80 | 80 |
| | Flow rate of Ar gas (sccm) | 0 | 0 | 0 | 0 | 0 | 0 | 0 |
| | Thickness (nm) | 5 | 10 | 20 | 50 | 10 | 10 | 10 |
| Piezoelectric thin | Film formation pressure (Pa) | 0.2 | 0.2 | 0.2 | 0.2 | 0.2 | 0.2 | 0.2 |
| film (aluminum | Power density (W/cm²) | 7.1 | 7.1 | 7.1 | 7.1 | 7.1 | 7.1 | 7.1 |
| nitride) | Flow rate of nitrogen gas (sccm) | 40 | 40 | 40 | 40 | 20 | 20 | 40 |
| | Flow rate of Ar gas (sccm) | 0 | 0 | 0 | 0 | 20 | 20 | 0 |
| | Thickness (nm) | 1,000 | 1,000 | 1,000 | 1,000 | 1,000 | 1,000 | 1,000 |
| Piezoelectric | C/m² | 1.2 | 1.1 | 1.2 | 1.2 | 1.1 | 0.8 | 0.8 |
| constant e₃₁^{f} | | | | | | | | |

TABLE 5

| Example | | 27 | 28 | 29 | 30 | 31 | 32 |
|---|---|---|---|---|---|---|---|
| Substrate | | SiSiO | SiSiO | SiSiO | Alkali- | Alkali- | Quartz |
| | | | | | free | free | |
| Film formation device | | A | A | A | A | A | A |
| Base layer | Material | | ZrN | | | ZrN | ZrN |
| | Flow rate of nitrogen gas (sccm) | | 80 | | | 80 | 80 |
| | Flow rate of Ar gas (sccm) | | 0 | | | 0 | 0 |
| | Thickness (nm) | | 10 | | | 10 | 10 |
| Electrode layer | Material | Ti | Ti | Ti | Ti | Ti | Ti |
| | Thickness (nm) | 100 | 100 | 100 | 100 | 100 | 100 |
| Base layer | Material | ZrN | ZrN | ZrN | ZrN | ZrN | ZrN |
| | Flow rate of nitrogen gas (sccm) | 80 | 80 | 80 | 80 | 80 | 80 |
| | Flow rate of Ar gas (sccm) | 0 | 0 | 0 | 0 | 0 | 0 |
| | Thickness (nm) | 10 | 10 | 10 | 10 | 10 | 10 |
| Piezoelectric thin | Film formation pressure (Pa) | 0.2 | 0.2 | 0.2 | 0.2 | 0.2 | 0.2 |
| film (aluminum | Power density (W/cm²) | 7.1 | 7.1 | 7.1 | 7.1 | 7.1 | 7.1 |
| nitride) | Flow rate of nitrogen gas (sccm) | 40 | 40 | 40 | 40 | 40 | 40 |
| | Flow rate of Ar gas (sccm) | 0 | 0 | 0 | 0 | 0 | 0 |
| | Thickness (nm) | 1,000 | 1,000 | 500 | 1,000 | 1,000 | 1,000 |
| Piezoelectric | C/m² | 1.6 | 1.4 | 0.7 | 0.8 | 0.9 | 0.9 |
| constant e₃₁^{f} | | | | | | | |

Examples 1 to 6 in Table 1 and Examples 7 to 13 in Table 2 show results of measuring the piezoelectric response of the piezoelectric laminate 100 in which the base layer 103 and the piezoelectric thin film 104 are formed in this order on the substrate 101 by changing a film thickness of the base layer 103 and the formation conditions of the piezoelectric thin film 104 in a case where the substrate 101 is the conductive Si.

Examples 14 to 19 in Table 3 show results of measuring the piezoelectric response of the piezoelectric laminate 100 in a case where the substrate 101 is a SiSiO, and Examples 20 to 24 in Table 4 show results of measuring the piezoelectric response of the piezoelectric laminate 100 prepared by using Pt for the electrode layer 102 and changing the film thickness of the base layer 103 and the formation conditions of the piezoelectric thin film 104 in a case where the substrate 101 is an alkali-free glass.

Example 25 in Table 4 shows results of measuring the piezoelectric response of the piezoelectric laminate 100 in a case where the substrate 101 is an alkali-free glass, and Example 26 in Table 4 shows results of measuring the piezoelectric response of the piezoelectric laminate 100 prepared by using ITO for the electrode layer 102 and changing the film thickness of the base layer 103 in a case where the substrate 101 is a quartz glass.

In Table 5, Examples 27 to 29 show results of measuring the piezoelectric response of the piezoelectric laminate 100 in a case where the substrate 101 is a SiSiO, Examples 30 and 31 show results of measuring the piezoelectric response of the piezoelectric laminate 100 in a case where the substrate 101 is an alkali-free glass, and Example 32 shows results of measuring the piezoelectric response of the piezoelectric laminate 100 prepared by using Ti for the electrode layer 102 on the substrate 101 and changing the film thickness of the base layer 103 in a case where the substrate 101 is a quartz glass. In addition, in Examples 28, 31, and 32, the base layer 103′ is included between the substrate 101 and the electrode layer 102.

From these results, it is understood that by a configuration in which the base layer 103 is included between the electrode layer 102 and the piezoelectric thin film 104, a piezoelectric laminate 100 in which the influence of the base (substrate or electrode layer) and the film formation conditions is eliminated and the piezoelectric performance is excellent is obtained as compared to a configuration in which the base layer 103 is not included.

Note that, the present application is based on a Japanese Patent Application No. 2023-187762 filed on Nov. 1, 2023, contents of which are incorporated herein by reference.

### REFERENCE SIGNS LIST

100: piezoelectric laminate
101: substrate
102: electrode layer
103, 103′: base layer
104: piezoelectric thin film
105: laminated film

1. A piezoelectric laminate, comprising:
a substrate; and
a laminated film provided on at least one surface of the substrate, wherein
the laminated film comprises, in order from a substrate side, an electrode layer, a base layer, and a piezoelectric thin film,
the base layer and the piezoelectric thin film are in contact with each other,
the base layer contains a nitrogen compound containing at least one element selected from the group consisting of Group III to VI elements, and
the piezoelectric thin film has an absolute value |e₃₁^{f}| of a piezoelectric constant of 0.5 C/m² or more.

2. A piezoelectric laminate, comprising:
a substrate; and
a laminated film provided on at least one surface of the substrate, wherein
the laminated film comprises, in order from a substrate side, an electrode layer, a base layer, and a piezoelectric thin film,
the base layer and the piezoelectric thin film are in contact with each other, and
the base layer contains a nitrogen compound, the nitrogen compound containing at least one element selected from the group consisting of Group III to VI elements and excluding zirconium nitride.

3. The piezoelectric laminate according to claim 1, wherein
the piezoelectric thin film contains aluminum nitride, and
the aluminum nitride has a hexagonal wurtzite structure oriented in a c-axis direction.

4. The piezoelectric laminate according to claim 2, wherein
the piezoelectric thin film contains aluminum nitride, and
the aluminum nitride has a hexagonal wurtzite structure oriented in a c-axis direction.

5. The piezoelectric laminate according to claim 1, wherein
the base layer has a sodium chloride structure, a fluorite structure, or a perovskite structure.

6. The piezoelectric laminate according to claim 2, wherein
the base layer has a sodium chloride structure, a fluorite structure, or a perovskite structure.

7. The piezoelectric laminate according to claim 1, wherein
the base layer has a (111) plane preferential orientation structure that is preferentially oriented in a (111) plane direction.

8. The piezoelectric laminate according to claim 2, wherein
the base layer has a (111) plane preferential orientation structure that is preferentially oriented in a (111) plane direction.

9. The piezoelectric laminate according to claim 1, wherein
the base layer is a nitrogen compound containing at least one element selected from the group consisting of Zr, Hf, Y, W, and Nb.

10. The piezoelectric laminate according to claim 2, wherein
the base layer is a nitrogen compound containing at least one element selected from the group consisting of Hf, Y, W, and Nb.

11. The piezoelectric laminate according to claim 1, wherein
the base layer has a thickness of 0.2 nm or more and 100 nm or less.

12. The piezoelectric laminate according to claim 2, wherein
the base layer has a thickness of 0.2 nm or more and 100 nm or less.

13. The piezoelectric laminate according to claim 11, wherein
the base layer has the thickness of 5 nm or more and 70 nm or less.

14. The piezoelectric laminate according to claim 12, wherein
the base layer has the thickness of 5 nm or more and 70 nm or less.

15. The piezoelectric laminate according to claim 1, wherein
the piezoelectric thin film has a thickness of 100 nm or more and 10 μm or less.

16. The piezoelectric laminate according to claim 2, wherein
the piezoelectric thin film has a thickness of 100 nm or more and 10 μm or less.

17. A piezoelectric element comprising the piezoelectric laminate according to claim 1.

18. A piezoelectric element comprising the piezoelectric laminate according to claim 2.

19. A method for manufacturing a piezoelectric laminate comprising a substrate and a laminated film provided on at least one surface of the substrate, the method comprising:
preparing the substrate; and
forming an electrode layer, a base layer, and a piezoelectric thin film on at least one surface of the substrate in this order, wherein
the base layer contains a nitrogen compound containing at least one element selected from the group consisting of Group III to VI elements,
the piezoelectric thin film is formed so as to be in contact with the base layer, and
the piezoelectric thin film has an absolute value |e₃₁^{f}| of a piezoelectric constant of 0.5 C/m² or more.

20. A method for manufacturing a piezoelectric laminate comprising a substrate and a laminated film provided on at least one surface of the substrate, the method comprising:
preparing the substrate; and
forming an electrode layer, a base layer, and a piezoelectric thin film on at least one surface of the substrate in this order, wherein
the base layer contains a nitrogen compound, the nitrogen compound containing at least one element selected from the group consisting of Group III to VI elements and excluding zirconium nitride, and
the piezoelectric thin film is formed so as to be in contact with the base layer.

21. The method for manufacturing a piezoelectric laminate according to claim 19, wherein
the forming is performed by a sputtering method.

22. The method for manufacturing a piezoelectric laminate according to claim 20, wherein
the forming is performed by a sputtering method.
